(19) United States
(12) Patent Application Publication
(10) Pub. No.: US 2025/0314430 A1
(43) Pub. Date: Oct. 9, 2025

(54) VAPOR SOAKING PLATE AND MODIFIED MANUFACTURING METHOD THEREFOR

(71) Applicant: National Taipei University of Technology, Taipei City (TW)

(72) Inventors: CHERNG-YUH SU, Taipei City (TW); HUAN-CHEN WU, New Taipei City (TW)

(73) Assignee: National Taipei University of Technology, Taipei City (TW)

(21) Appl. No.: 18/685,077

(22) PCT Filed: Aug. 10, 2022
(86) PCT No.: PCT/CN2022/111352

§ 371 Date: Sep. 5, 2024

(30) Foreign Application Priority Data
Aug. 19, 2021 (CN) 202110953098.2

(51) Int. Cl. F28D 15/04; F28F 21/04

(52) U.S. Cl. CPC F28D 15/046; F28F 21/04; F28F 2245/02; F28F 2255/20

(57) ABSTRACT

A vapor soaking plate includes a hollow board body having a chamber space therein. A surface of an upper side of the chamber space has a super-hydrophilic microstructure layer formed by modification. A porous structure is disposed on a lower side of the chamber space. An air chamber having a thickness below 0.4 mm is disposed between the surface of the upper side of the chamber space and the porous structure. Several guide posts are distributed in the air chamber. During a thermal conduction of the vapor soaking plate, after evaporating in an evaporator section of the porous structure, a working fluid condenses into a liquid film when the working fluid touches a surface of the super-hydrophilic microstructure layer of the chamber space. Subsequently, the working fluid flows back to the evaporator section along a wall surface of the air chamber or a surface of each of the guide posts.

### BACKGROUND OF THE INVENTION

### Technical Field

The present invention relates generally to a heat dissipation device and a manufacturing method thereof, and more particularly to a vapor soaking plate and a manufacturing method thereof.

### Description of Related Art

A structure of a conventional vapor soaking plate includes an upper cover body and a lower cover body which is joined to the upper cover body. A chamber body which is low vacuum is disposed in an inner portion of the conventional vapor soaking plate. A working fluid is disposed in the chamber body. A space of the chamber body is divided into an evaporator section and a condenser section. When a heat of a heat source is conducted to the evaporator section, the working fluid absorbs a thermal energy, so that a volume of the working fluid quickly increases and the working fluid vaporizes into a vapor to flow to the condenser section with a low pressure. When the vapor is in contact with a wall surface of the condenser section, the vapor condenses and releases a heat to become a liquid again to drop in the evaporator section or to flow back to the evaporator section by a capillary action of a wall surface of the chamber body. In this way, a cycling heat dissipation system is provided.

When the working fluid condenses on the wall surface of the condenser section of the vapor soaking plate, a thermal resistance generated by a thin film condensed phenomena originated from a hydrophilic surface of the condenser section is greater than a thermal resistance generated by a plurality of droplets of the working fluid condensing because of a hydrophobic surface of the condenser section. Therefore, even a thickness of the conventional vapor soaking plate is low, a wall surface of the evaporator section is designed to be hydrophilic and a wall surface of a periphery of the condenser section is designed to be hydrophobic according to the aforementioned design rationale. In general, when a contact angle between a surface of an object and a droplet dropped onto the surface of the object is between 10° and 90°, the object is defined to be hydrophilic. When a contact angle between a surface of an object and a droplet dropped onto the surface of the object is between 90° and 120°, the object is defined to be hydrophobic. When a contact angle between a surface of an object and a droplet dropped onto the surface of the object is less than 10° or even equal to 0°, the object is defined to be super-hydrophilic.

However, based on the aforementioned design of the conventional vapor soaking plate, because a hydrophobic layer is formed on an inner surface of the upper cover body, the vapor of the working fluid condenses on an inner wall of the upper cover body and drops. With such a structure of the conventional vapor soaking plate, the conventional vapor soaking plate could function normally in general applications and even have a desirable heat dissipation efficiency. However, through experiments and observations, once the thickness of the vapor soaking plate and the thickness of the chamber body are less than 1 mm and reach an ultra-thin level, the droplets of the working fluid would start to accumulate and join to one another on a microstructure of the lower cover body to form a plurality of water pillars. The formation of the water pillars hinders the vapor of the working fluid from moving upward and generates a flow resistance against the working fluid when the working fluid flows back to the evaporator section by the capillary action.

### BRIEF SUMMARY OF THE INVENTION

In view of the above, the primary objective of the present invention is to provide a vapor soaking plate that is ultra-thin, wherein a thickness of an inner space of the vapor soaking plate is less than a thickness of a conventional vapor soaking plate. Through a super-hydrophilic microstructure layer formed on a surface inside the vapor soaking plate, when a vapor of a working fluid condenses, a water film is formed and the working fluid flows back along a periphery of the surface inside the vapor soaking plate and a surface of each of a plurality of guide posts, so that a plurality of droplets could be prevented from forming a plurality of enormous water pillars. In this way, the capillary force, the efficiency of a condensed liquid of the working fluid flowing back, and the heat dissipation efficiency could be enhanced without affecting the flow of the vapor and a liquid of the working fluid.

The present invention provides a vapor soaking plate comprising a hollow board body, a porous structure, and a plurality of guide posts, wherein the hollow board body has a chamber space therein; a surface of an upper side of the chamber space has a super-hydrophilic microstructure layer formed by modification; the porous structure is disposed on a lower side of the chamber space and is adapted to be adsorbed by a working fluid; an air chamber is disposed between the surface of the upper side of the chamber space and the porous structure; a thickness of the air chamber is less than or equal to 0.4 mm; the guide posts are distributed in the air chamber and are adapted to support the air chamber.

In an embodiment, the hollow board body includes an upper cover and a lower cover joined to the upper cover; the upper cover has an upper recess inside the upper cover; the super-hydrophilic microstructure layer formed by modification is located on a surface of the upper recess; the lower cover has a lower recess inside the lower cover; the lower recess and the upper recess communicate with each other to form the chamber space; the porous structure is disposed in the lower recess; the air chamber is located between the upper recess and the porous structure.

The present invention further provides a manufacturing method of the vapor soaking plate, including: preparing components of the vapor soaking plate, performing a thermal oxidation process, joining the components of the vapor soaking plate, and completing an end product of the vapor soaking plate; preparing the components of the vapor soaking plate is to prepare the vapor soaking plate, wherein the components of the vapor soaking plate includes the upper cover, the lower cover, and the porous structure; the upper cover has the upper recess; the lower cover has the lower recess; the guide posts are disposed in the upper recess; the porous structure is disposed in the lower recess; performing the thermal oxidation process represents that placing the upper cover of the vapor soaking plate, the lower cover of the vapor soaking plate, and the porous structure of the vapor soaking plate in a furnace, injecting oxygen into the furnace, and heating the furnace at a maximum temperature of 450° C., a heating rate of 10° C./min, a cooling rate of 10° C./min, and an oxygen flow rate of 200 sccm for 30 minutes. Cooling by furnace cooling, wherein a super-hydrophilic microstructure layer is formed on at least the surface of the upper recess; joining the components of the vapor soaking plate represents that joining the upper cover to the lower cover; the air chamber is formed between the upper recess and the porous structure; the thickness of the air chamber is less than or equal to 0.4 mm; an inlet communicating with the air chamber is disposed on a periphery of the vapor soaking plate; completing the end product of the vapor soaking plate represents that filling the vapor soaking plate with water through the inlet, vacuuming the vapor soaking plate, and sealing the inlet to complete the end product of the vapor soaking plate.

With the aforementioned design, through the manufacturing method, the vapor soaking plate is manufactured in a manner that the super-hydrophilic microstructure layer is at least formed on the surface of the upper side of the chamber space. When the ultra-thin vapor soaking plate is used for thermal conduction and the working fluid evaporating from the evaporator section of the side of the porous structure is in contact with the cooler surface of the upper side of the chamber space, the working fluid condenses into the water film on the surface of the super-hydrophilic microstructure layer and does not drop, so that the limited space of the air chamber could be fully used by the water film in a manner that the water film flows back to the porous structure along the wall surface of the periphery of the air chamber or the surface of each of the guide posts for cycling continuously. In this way, the formation of the enormous water pillars, which hinders the vapor of the working fluid and the liquid of the working fluid from flowing, could be prevented and the vapor of the working fluid could be prevented from being in contact with the enormous water pillars to condense early, and the capillary force, the efficiency of the condensed liquid of the working fluid flowing back, and the heat dissipation efficiency could be enhanced.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a sectional schematic view of the vapor soaking plate according to an embodiment of the present invention;

FIG. 2 is a schematic view of the vapor soaking plate, showing an operation of the vapor soaking plate according to the embodiment of the present invention;

FIG. 3A and FIG. 3B are electron microscope images of the super-hydrophilic microstructure layer of the surface of the upper recess according to the embodiment of the present invention;

FIG. 4A and FIG. 4B are electron microscope images of the super-hydrophilic microstructure layer of a copper mesh surface according to the embodiment of the present invention;

FIG. 5 is a flow chart of the manufacturing method of the vapor soaking plate according to the embodiment of the present invention;

FIG. 6 is a schematic view of the manufacturing method of the vapor soaking plate according to the embodiment of the present invention;

FIG. 7 is a schematic view of the vapor soaking plate, showing the vapor soaking plate is disposed to undergo a thermal characteristic measurement according to the embodiment of the present invention;

FIG. 8A and FIG. 8B respectively show a line graph of a heating power and a cycling thermal resistance by a horizontal measurement and a line graph of the heating power and the cycling thermal resistance by a vertical measurement;

FIG. 9A and FIG. 9B respectively show a line graph of the heating power and a temperature difference of two points by the horizontal measurement and a line graph of the heating power and the temperature difference of two points by the vertical measurement.

### DETAILED DESCRIPTION OF THE INVENTION

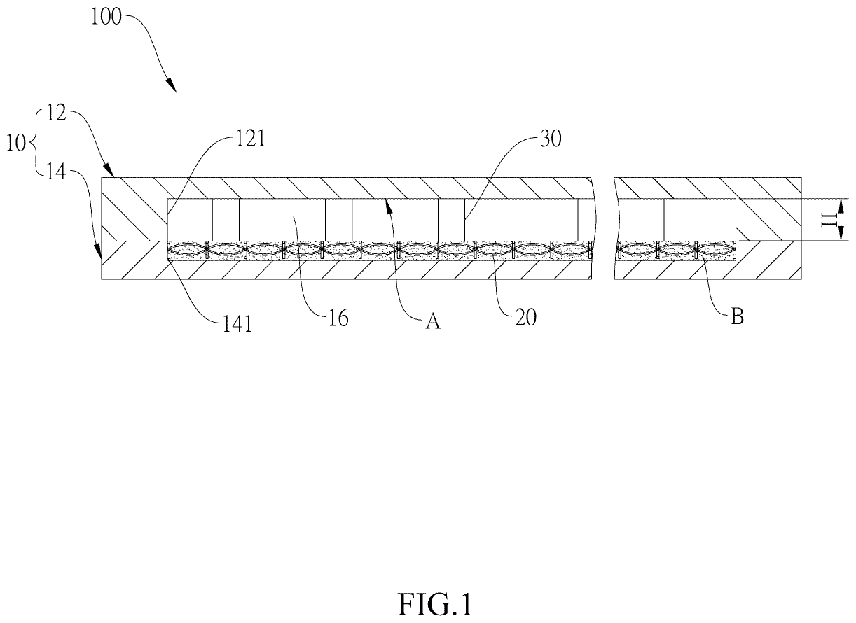

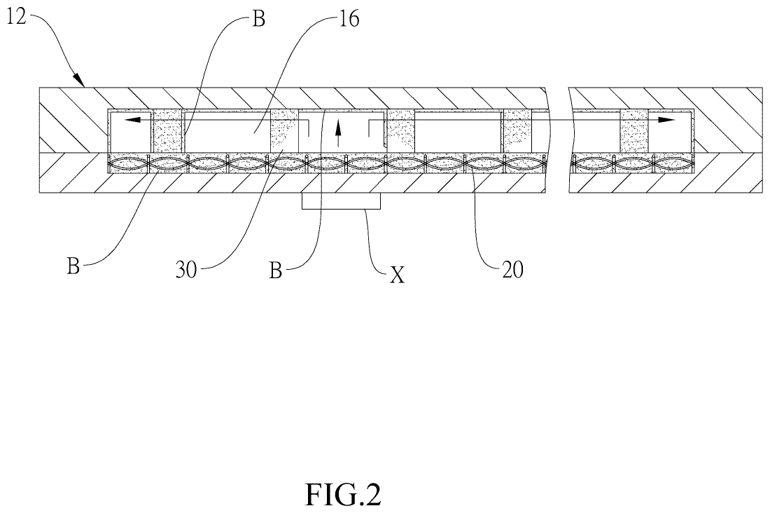

A vapor soaking plate 100 according to an embodiment of the present invention is illustrated in FIG. 1 and FIG. 2. To achieve a desirable thermal conduction and a desirable heat dissipation, a whole of the vapor soaking plate 100 is preferably made of copper which is a good heat conductor. The vapor soaking plate 100 includes a hollow board body 10, a porous structure 20, and a plurality of guide posts 30.

The hollow board body 10 includes an upper cover 12 and a lower cover 14 joined to the upper cover 12. The upper cover 12 has an upper recess 121 inside the upper cover 12. A surface of the upper recess 121 has a super-hydrophilic microstructure layer A formed by modification. Preferably, a contact angle between a plurality of droplets adsorbed on a surface of the super-hydrophilic microstructure layer A and the surface of the super-hydrophilic microstructure layer A is nearly 0°, so that the super-hydrophilic microstructure layer A is a super-hydrophilic surface structure. The lower cover 14 has a lower recess 141 inside the lower cover 14. A periphery edge of the lower cover 14 is joined to a periphery edge of the upper cover 12 by welding, so that the lower recess 141 and the upper recess 121 communicate with each other to form a chamber space C inside the hollow board body 10.

The porous structure 20 could be a copper mesh structure combined with the lower recess 141, a sintered structure formed in the lower recess 141, or an etched structure formed in the lower recess 141. In the current embodiment, the porous structure 20 is the copper mesh structure combined with the lower recess 141 and is disposed on a lower side of the chamber space C. A wire diameter of the porous structure 20 is 0.04 mm. A mesh number of the porous structure 20 is 250. The porous structure 20 is adapted to be adsorbed by a working fluid B. An air chamber 16 is disposed between a wall surface of an upper side of the upper recess 121 (i.e., a surface of an upper side of the chamber space C) and a surface of an upper side of the porous structure 20. A thickness H of the air chamber 16 is less than or equal to 0.4 mm. Preferably, the thickness H of the air chamber 16 is between 0.05 mm and 0.3 mm. In this way, through the thickness H of the air chamber 16, a thickness of the whole of the vapor soaking plate 100 is obviously less than a thickness of a conventional vapor soaking plate, so that the vapor soaking plate 100 is called an ultra-thin vapor soaking plate.

The guide posts 30 are distributed in the air chamber 16 and are adapted to support the air chamber 16 to prevent an inner wall of the upper cover 12 from collapsing in a direction of the lower cover 14. Meanwhile, when the vapor soaking plate 100 operates, a surface of each of the guide posts 30 guides a water film to flow back to the porous structure 20. Preferably, a diameter of each of the guide posts 30 is 1 mm, and an interval between any adjacent two of the guide posts 30 is 3 mm.

In the current embodiment, the chamber space C inside the hollow board body 10 includes an upper recess 121 and a lower recess 141, but not limited thereto. For example, in other embodiments, the recess could be only disposed in the upper cover 12 or the lower cover 14 and then be joined to the other of the lower cover 14 and the upper cover 12, which is flat, in a sealed way to form the hollow board body 10. In this way, the chamber space C could be provided inside the hollow board body 10.

Referring to FIG. 1 and FIG. 2, when the vapor soaking plate 100 is used for thermal conduction and heat dissipation, a heat source X is in contact with a side of the lower cover 14; the working fluid B is adsorbed in the porous structure 20 in the lower recess 141 is heated to evaporate into a vapor. To illustrate easily how the working fluid B operates hereafter, an area in which the working fluid B is heated to evaporate into the vapor is defined as an evaporator section. After the working fluid B is evaporated into the vapor, the vapor quickly flows to a periphery with a lower atmospheric pressure, i.e., the vapor quickly flows to a periphery of the air chamber 16. When the vapor is in contact with an area in the upper recess 121 of which a temperature is lower and especially is in contact with a surface of the area, the vapor condenses. Therefore, the surface of the upper recess 121 is defined as a condenser section.

When the vapor of the working fluid B is cooled to condense in the condenser section, the cooled working fluid B condenses into the water film in the condenser section and does not drop in a direction of the porous structure 20 because the super-hydrophilic microstructure layer A has a characteristic of superhydrophilicity to be fully moist. In this way, even when the thickness H is in the ultra-thin level and the air chamber 16 is only provided with a limited space, the droplets could be prevented from joining to one another to form a plurality of enormous water pillars which hinders the vapor from flowing in the air chamber 16, thereby preventing the flow of the vapor generated by the evaporation of the working fluid B from being obstructed. Moreover, the working fluid B, which is condensed into the water film, could be prevented from flowing back in the direction of the porous structure 20 along the surface of each of the guide posts 30 or a wall surface of a periphery of the upper recess 12. Additionally, the vapor could be prevented from being in contact with the enormous water pillars to condense as a liquid before the vapor arrives in the condenser section, so that reducing an operation efficiency of a thermal cycle could be avoided.

Because a capillary action is intensified by the porous structure 20, the working fluid B flowing back to the porous structure 20 supplements the evaporator section which dries up due to evaporation, so that the working fluid B in the evaporator section could be heated to boil into the vapor again for the subsequent thermal cycle. In addition, the working fluid B flowing back to the porous structure 20 could also help a plurality of bubbles generated by the working fluid B leave the evaporator section, so that a higher heat flux could be achieved. Through the ultra-thin vapor soaking plate 100 having the super-hydrophilic microstructure layer A on the surface of the upper recess 121 according to the embodiment of the present invention, the working fluid B could adapt to the air chamber 16 with the ultra-thin thickness H and could diffuse in a gas phase between the evaporator section and the condenser section and then flow back in a liquid phase and in a thin film in the continuous thermal cycle, thereby forming a good heat dissipation cycling system.

The detailed structure of the vapor soaking plate 100 according to the embodiment of the present invention is illustrated in detail in the below description. The upper recess 121 of the upper cover 12 is formed by etching a copper sheet with a thickness of 0.2 mm, wherein an etched depth is 0.15 mm. The upper cover 12 is etched to form the upper recess 121, and meanwhile the guide posts 30 connected to the surface of the upper recess 121 are formed. The lower recess 141 of the lower cover 14 is formed by etching a copper sheet with a thickness of 0.1 mm, wherein an etched depth is 0.05 mm. A thickness of the porous structure 20 of a copper mesh combined with the lower recess 141 is 0.05 mm and the thickness H of the air chamber 16 is 0.15 mm.

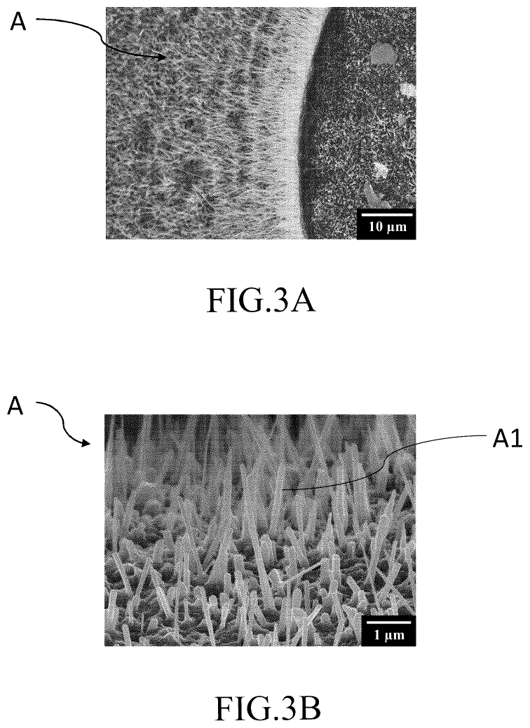

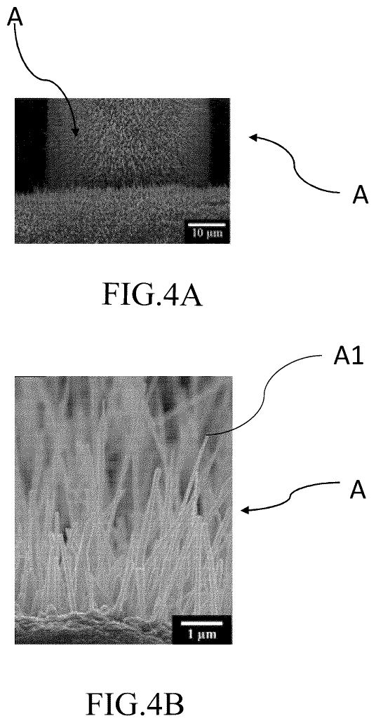

In addition to the vapor soaking plate 100 of the embodiment that the surface of the upper recess 121 has the super-hydrophilic microstructure layer A formed by modification, another super-hydrophilic microstructure layer A formed by modification could be selectively formed on the surface of each of the guide posts 30, the surface of the porous structure 20, or both the surface of each of the guide posts 30 and the surface of the porous structure 20. Alternatively, the super-hydrophilic microstructure layer A could also be formed on a surface of the lower recess 141. Referring to FIG. 3A to FIG. 4B, each of the super-hydrophilic microstructure layers A is a nanoscale copper oxide microstructure and has a plurality of nanowires A1 made of copper oxide. The surface of the upper recess 121, the super-hydrophilic microstructure layer A of the surface of each of the guide posts 30, and the nanowires A1 thereof are shown in FIG. 3A and FIG. 3B. The super-hydrophilic microstructure layer A of the porous structure 20 of the copper mesh and the nanowires A1 thereof are shown in FIG. 4A and FIG. 4B. Through the super-hydrophilic microstructure layer A formed on the surface of the porous structure 20, the porous structure 20 could further enhance a capillary force, so that after the working fluid B flows back to the porous structure 20, the working fluid B could quickly flow to the heated evaporator section to undergo again the thermal cycle containing the evaporation and the condensation.

Preferably, a diameter of each of the nanowires A1 is between 50 nm and 400 nm, a length of each of the nanowires A1 is between 1 μm and 10 μm, and an area occupied by the nanowires A1 per unit area of the super-hydrophilic microstructure layer A is between 20% and 70%. Each of the super-hydrophilic microstructure layers A could generate a super-hydrophilic phenomenon when the nanowires A1 are in contact with the liquid, so that the liquid could form the water film on the surface of each of the super-hydrophilic microstructure layers A and the capillary force could be improved.

Each of the super-hydrophilic microstructure layers A benefits from an extremely small thermal resistance and an enlarged contact area of the nanowires A1, so that a heat flux of a surface on which each of the super-hydrophilic microstructure layers A is located, such as the surface of the upper recess 121, the surface of the lower recess 141, the surface of the porous structure 20, and the surface of each of the guide posts 30 could be further enhanced, thereby raising a heat exchange efficiency. For example, the flow generated by the capillary action of the porous structure 20 could stimulate the bubbles of the working fluid B evaporating in the evaporator section to leave the evaporator section. After the super-hydrophilic microstructure layer A is formed on the surface of the porous structure 20, the nanowires A1 could further reduce the thermal resistance of the porous structure 20 and raise an area of the thermal conduction, so that the evaporation of the working fluid B in the evaporator section could be stimulated, thereby raising an efficiency of the evaporation and reducing a thermal resistance of the evaporation. In this way, a heat exchange efficiency of the vapor soaking plate 100 and a thermal characteristic of the vapor soaking plate 100 could be improved.

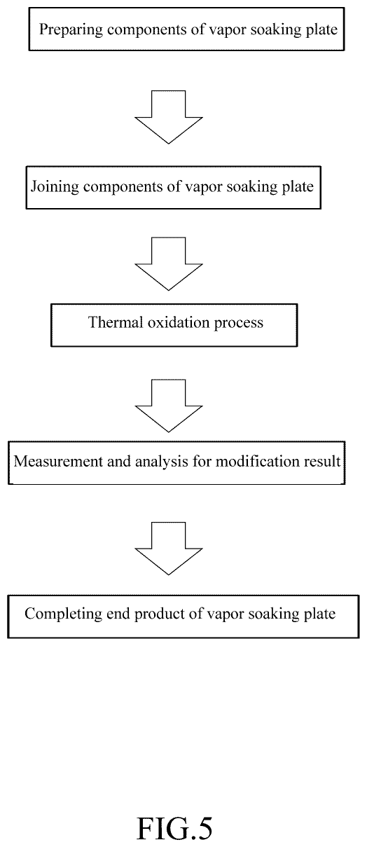

In the embodiment, the vapor soaking plate 100 is manufactured by a manufacturing method of a vapor soaking plate. FIG. 5 shows a flow chart of the manufacturing method of the vapor soaking plate 100. The manufacturing method of the vapor soaking plate 100 includes the following steps:

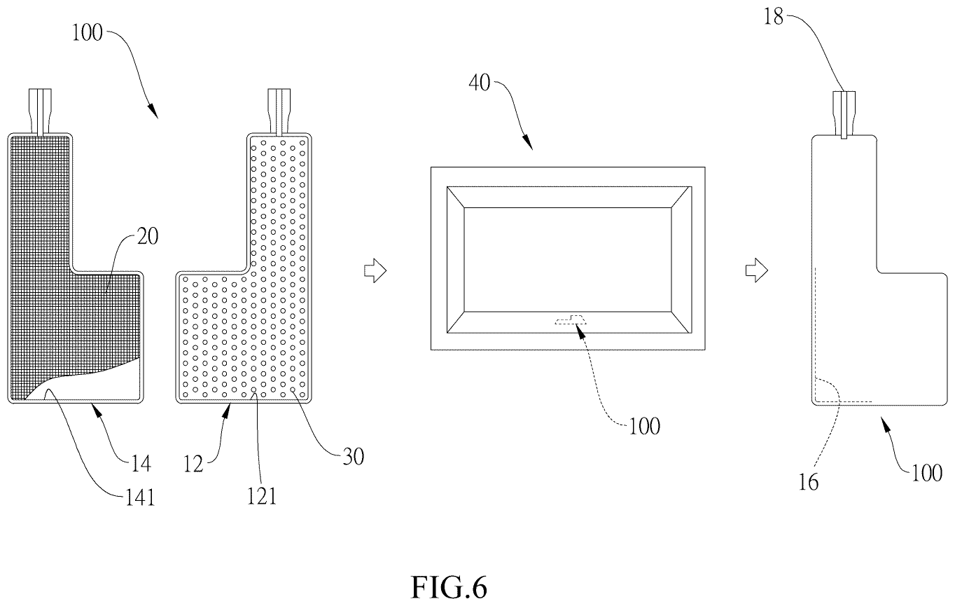

Preparing components of a vapor soaking plate: referring to FIG. 6, the components of the vapor soaking plate 100 are prepared, wherein the components of the vapor soaking plate 100 include the upper cover 12, the lower cover 14, and the porous structure 20. The upper cover 12 is a copper sheet and has the upper recess 121 formed by etching. The lower cover 14 is a copper sheet and has the lower recess 141 formed by etching. The upper cover 12 is etched to form the upper recess 121, and meanwhile a plurality of guide posts 30 connected to the surface of the upper recess 121 is formed. The porous structure 20 is disposed in the lower recess 141. In the current embodiment, the porous structure 20 is a copper mesh having a wire diameter of 0.04 mm and a mesh number of 250.

Preferably, the porous structure 20 could also be a sintered structure or an etched structure and a size of each of the components of the vapor soaking plate 100 is as follows; a thickness of the upper cover 12 is 0.2 mm, a thickness of the lower cover 14 is 0.1 mm, an etched depth of the upper recess 121 is 0.15 mm, an etched depth of the lower recess 141 is 0.05 mm, a diameter of each of the guide posts 30 is 1 mm, and an interval between any adjacent two of the guide posts 30 is 3 mm.

Joining the components of the vapor soaking plate 100: the upper cover 12 is joined to the lower cover 14 by welding, so that the vapor soaking plate 100 is provided with a hollow board body 10 having a chamber space C inside the hollow board body 10 and being in a shape of a thin sheet. Referring to FIG. 1, the upper recess 121 and the lower recess 141 communicate with each other to form the chamber space C. An air chamber 16 is formed between a wall surface of an upper side of the upper recess 121 inside the vapor soaking plate 100 and the porous structure 20. A thickness H of the air chamber 16 is less than or equal to 0.4 mm. An inlet 18 communicating with the air chamber 16 is disposed in a periphery of the vapor soaking plate 100.

Performing a thermal oxidation process: the upper cover 12 of the vapor soaking plate 100, the lower cover 14 of the vapor soaking plate 100, and the porous structure 20 of the vapor soaking plate 100 are placed in a furnace 40. Oxygen is injected into the furnace 40. The furnace 40 is heated at a maximum temperature of 450° C., a heating rate of 10° C./min, a cooling rate of 10° C./min, and an oxygen flow rate of 200 sccm for 30 minutes. Afterwards, cooling is performed through furnace cooling, a super-hydrophilic microstructure layer A is formed on at least the surface of the upper recess 12. Preferably, during the thermal oxidation process, the surface of the upper recess 121, the surface of the lower recess 141, the surface of the porous structure 20, and each of the surfaces of the guide posts 30 are respectively modified to form the super-hydrophilic microstructure layer A. Each of the super-hydrophilic microstructure layers A includes a plurality of nanowires A1 made of copper oxide.

A measurement and an analysis for a modification result: after the step of the thermal oxidation process is completed, the measurement and the analysis for the modification result of the vapor soaking plate 100 are performed, wherein the measurement and the analysis include a contact angle measurement, a capillary force measurement, and a microstructure topography and phase analysis. In the contact angle measurement, through a contact angle measuring instrument, a wettability of a test piece of the porous structure 20 which is the copper mesh modified by the thermal oxidation process is compared with a wettability of a test piece of a copper mesh provided without the thermal oxidation process. A size of each of droplets of the contact angle measurement is 5 μl. A contact angle between the copper mesh and the droplet is measured and recorded by a high-speed camera. Compared with the contact angle of 95° of the copper mesh provided without the thermal oxidation process, that the contact angle obtained by the contact angle measurement and measured between the droplet located on the modified surface of the porous structure 20 of the copper mesh of the embodiment and the copper mesh is 0° is in a fully wet and super-hydrophilic state.

In the capillary force measurement, the lower cover 14 combined with the porous structure 20 of the copper mesh is positioned vertically in a vertical wicking test instrument. A lower portion of the lower cover 14 combined with the copper mesh is immersed in a liquid of a petri dish. When a capillary force of the porous structure 20 of the copper mesh and a capillary force of the copper mesh without the thermal oxidation process are measured, a depth of the copper mesh being immersed in the liquid is 1 cm. A ruler with scales is placed besides the lower cover 14 and is adapted to record a climbing time for the liquid to reach an upper portion of the copper mesh. The climbing time measured of the porous structure 20 of the copper mesh of the embodiment is 20 seconds. Compared with the copper mesh provided without the thermal oxidation process that has no capillary force, the porous structure 20 obviously has a better capillary force.

In the microstructure topography and phase analysis, the test piece of the porous structure 20 of the copper mesh modified by the thermal oxidation is observed by an electron microscope. Referring to FIG. 3A to FIG. 4B, the diameter of each of the nanowires A1 is between 50 nm and 400 nm. A length of each of the nanowires A1 is between 1 μm and 10 μm. An area occupied by the nanowires A1 per unit area is analyzed by an image analysis software. The area occupied by the nanowires A1 per unit area is 20% to 70% and a density of the nanowires A1 obtained is 0.5 to 3 wires per square micrometer. Preferably, the density of the nanowires A1 is 1.4 wires per square micrometer. The test piece is measured by a Raman spectrometer and an X-ray diffraction to confirm that the nanowires A1 of the super-hydrophilic microstructure layer A are copper oxide nanowires.

Completing an end product of the vapor soaking plate: the vapor soaking plate 100 is filled with water through the inlet 18 of the vapor soaking plate 100 and then is vacuumed. Subsequently, the inlet 18 is sealed and then the end product of the vapor soaking plate 100 is completed. After the end product of the vapor soaking plate 100 is completed, a thermal characteristic measurement of the vapor soaking plate 100 and a reliability testing of the vapor soaking plate 100 are operated.

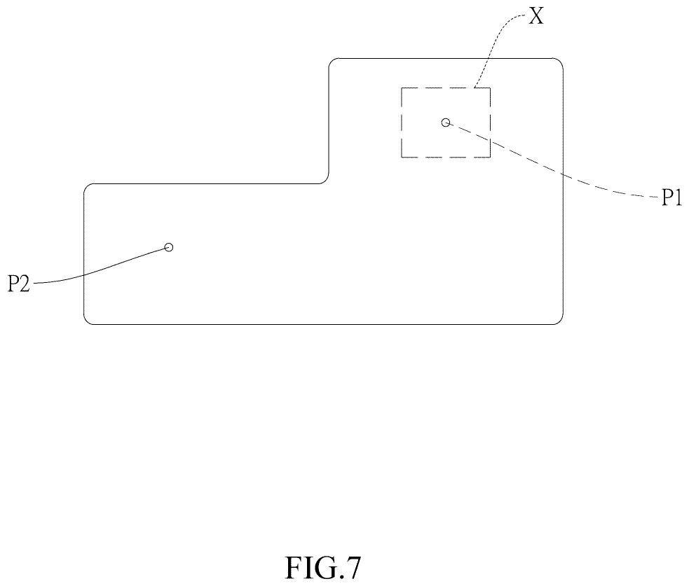

In the thermal characteristic measurement, a measurement environment is as follows: a natural heat dissipation, a horizontal placement of the vapor soaking plate 100, and a vertical placement of the vapor soaking plate 100, an environmental temperature of 25±1° C., and a start temperature of a heat source X of 30±1° C. Referring to FIG. 7, the heat source X is disposed on a lower surface of the vapor soaking plate 100. A first temperature measuring point P1 is disposed on an upper surface of the vapor soaking plate 100 at a location corresponding to the heat source X and a second temperature measuring point P2 is disposed on the upper surface of the vapor soaking plate 100 at a location spaced with the heat source X at a certain distance. A temperature measured at the first temperature measuring point P1 is T1. A temperature measured at the second temperature measuring point P2 is Tc. An equation of a temperature difference of two points ΔT (unit is ° C.) between the first temperature measuring point P1 and the second temperature measuring point P2 is ΔT=Tc−T1. An equation of a heating power Qᵢₙ (unit is Watt) of the heat source X of which an electricity is supplied by a DC power supply is Qᵢₙ (heating power)=I (current)×V (voltage). The heating power Qᵢₙ and the temperature difference of two points ΔT are substituted into the following equation of a cycling thermal resistance Rc:

$$Rc ( cycling thermal resistance ) = Δ T / {Q}_{i n}$$

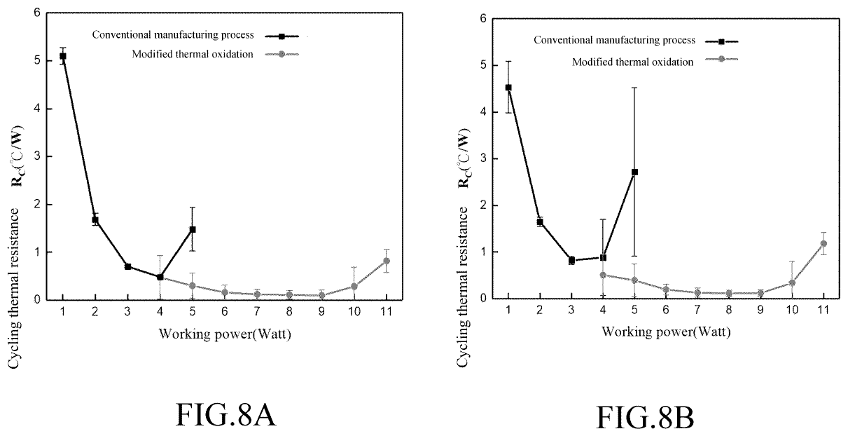

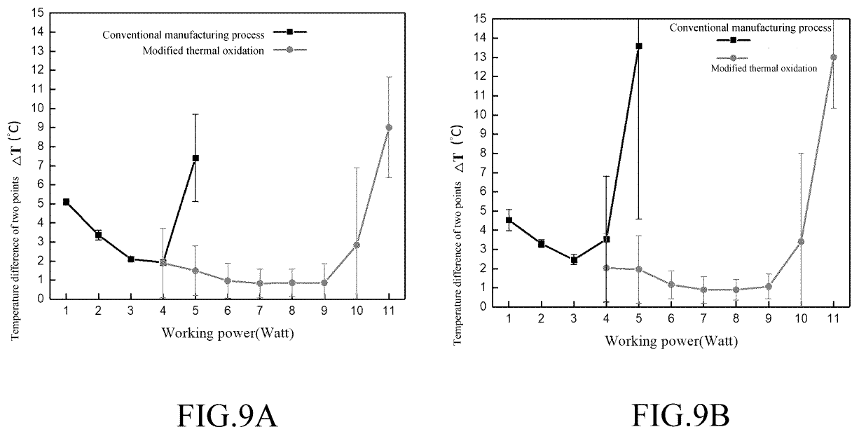

Values of the cycling thermal resistance Rc (unit is ° C./W) could be calculated. FIG. 8A and FIG. 8B show the values of the vapor soaking plate 100 modified by the thermal oxidation of the present invention and the values of a vapor soaking plate manufactured by a conventional manufacture process with the horizontal placement and the vertical placement, wherein a horizontal axis represents the heating power of the heat source X, and a vertical axis represents the cycling thermal resistance Rc. FIG. 9A and FIG. 9B show the values of the vapor soaking plate 100 modified by the thermal oxidation of the present invention and the values of the vapor soaking plate manufactured by the conventional manufacture process with the horizontal placement and the vertical placement, wherein a horizontal axis represents the heating power of the heat source X, and a vertical axis represents the temperature difference of two points ΔT.

The line graphs of the heating power and the cycling thermal resistance and the line graphs of the heating power and the temperature difference of two points shown in FIG. 8A to FIG. 9B show that a maximum operating power of the vapor soaking plate manufactured by the conventional manufacture process is between 3 and 4 Watt during a normal operation, but a maximum operating power of the vapor soaking plate 100 modified by the thermal oxidation of the present invention could be raised to 9 Watt during a normal operation, which represents the thermal characteristic of the vapor soaking plate 100 is obviously better than a thermal characteristic of the vapor soaking plate provided without the modification, and the thermal characteristic of the vapor soaking plate 100 is not affected no matter the vapor soaking plate 100 is placed horizontally or vertically.

It must be pointed out that the embodiments described above are only some preferred embodiments of the present invention. All equivalent structures which employ the concepts disclosed in this specification and the appended claims should fall within the scope of the present invention.

1.-11. (canceled)

12. A vapor soaking plate, comprising:
a hollow board body having a chamber space therein, wherein a surface of an upper side of the chamber space has a super-hydrophilic microstructure layer formed by modification;
a porous structure disposed on a lower side of the chamber space and adapted to be adsorbed by a working fluid, wherein an air chamber is disposed between the surface of the upper side of the chamber space and the porous structure; a thickness of the air chamber is less than or equal to 0.4 mm; and
a plurality of guide posts distributed in the air chamber and adapted to support the air chamber.

13. The vapor soaking plate as claimed in claim 12, wherein the hollow board body comprises an upper cover and a lower cover joined to the upper cover; the upper cover has an upper recess inside the upper cover; the super-hydrophilic microstructure layer formed by modification is located on a surface of the upper recess; the lower cover has a lower recess inside the lower cover; the lower recess and the upper recess communicate with each other to form the chamber space; the porous structure is disposed in the lower recess; the air chamber is located between the upper recess and the porous structure.

14. The vapor soaking plate as claimed in claim 13, wherein the porous structure is a copper mesh structure combined with the lower recess, a sintered structure formed in the lower recess, or an etched structure formed in the lower recess; each of the plurality of guide posts is connected to the surface of the upper recess.

15. The vapor soaking plate as claimed in claim 12, wherein a surface of each of the plurality of guide posts and a surface of the porous structure respectively have another super-hydrophilic microstructure layer formed by modification; each of the plurality of super-hydrophilic microstructure layers of the surface of each of the plurality of guide posts, each of the plurality of super-hydrophilic microstructure layers of the surface of the porous structure, and each of the plurality of super-hydrophilic microstructure layers of the surface of the upper side of the chamber space are nanoscale copper oxide microstructures and have a plurality of nanowires.

16. The vapor soaking plate as claimed in claim 15, wherein a diameter of each of the plurality of nanowires is between 50 nm and 400 nm; a length of each of the plurality of nanowires is between 1 μm and 10 μm.

17. The vapor soaking plate as claimed in claim 16, wherein an area occupied by the plurality of nanowires per unit area is between 20% and 70%.

18. The vapor soaking plate as claimed claim 12, wherein the thickness of the air chamber is between 0.05 mm and 0.3 mm.

19. A manufacturing method of the vapor soaking plate as claimed in claim 12, comprising:
preparing components of the vapor soaking plate: preparing the components of the vapor soaking plate, wherein the components of the vapor soaking plate comprise an upper cover, a lower cover, and the porous structure; the upper cover has an upper recess; the lower cover has a lower recess; the plurality of guide posts are disposed in the upper recess; the porous structure is disposed in the lower recess;
performing a thermal oxidation process: placing the upper cover of the vapor soaking plate, the lower cover of the vapor soaking plate, and the porous structure of the vapor soaking plate in a furnace, injecting oxygen into the furnace, and heating the furnace at a maximum temperature of 450° C., a heating rate of 10° C./min, a cooling rate of 10° C./min, and an oxygen flow rate of 200 sccm for 30 minutes; cooling by furnace cooling, wherein a super-hydrophilic microstructure layer is formed on at least a surface of the upper recess;
joining the components of the vapor soaking plate: joining the upper cover to the lower cover to form a hollow board body, wherein the upper recess and the lower recess communicates with each other to form the chamber space; the air chamber is formed between the upper recess and the porous structure; the thickness of the air chamber is less than or equal to 0.4 mm; an inlet communicating with the air chamber is disposed on a periphery of the vapor soaking plate; and
completing an end product of the vapor soaking plate: filling the vapor soaking plate with water through the inlet, vacuuming the vapor soaking plate, and sealing the inlet to complete the end product of the vapor soaking plate.

20. The manufacturing method of the vapor soaking plate as claimed in claim 19, wherein in the step of the thermal oxidation process, another super-hydrophilic microstructure layer formed by modification is formed on a surface of each of the plurality of guide posts and a surface of the porous structure.

21. The manufacturing method of the vapor soaking plate as claimed in claim 19, wherein each of the plurality of super-hydrophilic microstructure layers of a surface of each of the plurality of guide posts, each of the plurality of super-hydrophilic microstructure layers of a surface of the porous structure, and each of the plurality of super-hydrophilic microstructure layers of the surface of the the upper recess are nanoscale copper oxide microstructures and have a plurality of nanowires; a diameter of each of the plurality of nanowires is between 50 nm and 400 nm; a length of each of the plurality of nanowires is between 1 μm and 10 μm.

22. The manufacturing method of the vapor soaking plate as claimed in claim 20, wherein each of the plurality of super-hydrophilic microstructure layers of the surface of each of the plurality of guide posts, each of the plurality of super-hydrophilic microstructure layers of the surface of the porous structure, and each of the plurality of super-hydrophilic microstructure layers of the surface of the the upper recess are nanoscale copper oxide microstructures and have a plurality of nanowires; a diameter of each of the plurality of nanowires is between 50 nm and 400 nm; a length of each of the plurality of nanowires is between 1 μm and 10 μm.

23. The manufacturing method of the vapor soaking plate as claimed in claim 21, wherein an area occupied by the plurality of nanowires per unit area is between 20% and 70%.

24. The manufacturing method of the vapor soaking plate as claimed in claim 22, wherein an area occupied by the plurality of nanowires per unit area is between 20% and 70%.
